(19) United States
(12) Patent Application Publication
(10) Pub. No.: US 2016/0062002 A1
(43) Pub. Date: Mar. 3, 2016

(54) SILVERPLATED REFLECTING FILM AND MANUFACTURING METHOD THEREOF

(71) Applicant: NINGBO SOLARTRON TECHNOLOGY CO., LTD., Ningbo, Zhejiang (JP)

(72) Inventors: Yadong Jin, Cicheng Town Ningbo (CN); Yubo Zhou, Ningbo (CN)

(21) Appl. No.: 14/779,861

(22) PCT Filed: Oct. 24, 2013
(86) PCT No.: PCT/CN2013/085874

§ 371 Date: Sep. 24, 2015

(30) Foreign Application Priority Data
May 22, 2013 (CN) 201310195392.7

(51) Int. Cl. G02B 5/08; G02B 1/04; B29D 11/00; G02B 1/14; C23C 14/34; C23C 14/20

(52) U.S. Cl. CPC G02B 5/0866; C23C 14/34; C23C 14/205; B29D 11/00605; G02B 1/14; G02B 1/04; B29K 2667/00

(57) ABSTRACT

Disclosed are a silverplated reflecting film and a manufacturing method thereof. The reflecting film comprises a reflecting polyester film layer (3), a silverplated layer (2) and a protection layer (1). The reflecting polyester film layer (3) contains 5-25% nanometer modified inorganic filler. The reflecting film provided by the invention has a high reflectivity, and the manufacturing method has simply processes and is easy to operate.

### TECHNICAL FIELD OF THE INVENTION

The present invention relates to the technical field of reflecting films, in particular, to a silverplated reflecting film and a manufacturing method thereof.

### BACKGROUND OF THE INVENTION

A liquid crystal backlight system is primarily comprised of a light source, a light guide plate, all kinds of optical films and structural members, and its development tends to provide the diversified, light and portable size, and to meet the requirement of high luminance. Current types of backlight sources mainly contain electro luminescence (EL), cold cathode fluorescent tube (CCFL), light emitting diode (LED) etc., which are divided into a side-light type and an end backlight type according to different positions thereof. Along with the development of the LCD module, the side-light type CCFL backlight source of high brightness and thin profile becomes a main stream, but due to large power consumption, the power conservation requirement of a portable information product cannot be met. Therefore, improving the backlight source brightness to further increase the LCD brightness without increasing the power consumption is also one of the main trends of the development. How to improve the optical property of the reflecting film, improve the reflectivity thereof, and make the light emitted by the light source can be utilized to the fullest to reduce loss is an important subject that this field needs to solve at present.

At present, the reflecting film structure usually forms the white polyester film of porous structure via bubbles, the products such as Toray, SKC all intensively rely on the difference between the refractive indexes of the matrix resin and micropores or bubbles to improve reflectivity, namely controlling the center cell and the bubble density to improve reflectivity. However, the reflectivity of the foaming type white reflecting film can only reach 96-97%, and is difficult to be continuously improved.

### SUMMARY OF THE INVENTION

In order to overcome the deficiencies of the existing optical reflecting films, the present invention provides a silverplated reflecting film with a high reflectivity, which can reach 99% or more.

In order to solve the above-mentioned technical problems, the present invention provides the following technical solutions:

A silverplated reflecting film, wherein the reflecting film comprises a reflecting polyester film layer, a silverplated layer and a protection layer; wherein the silverplated layer is placed between the reflecting polyester film layer and the protection layer; and the reflecting polyester film layer contains 5-25% nanometer modified inorganic filler comprising filler particles, and the percentage is percentage by weight. Reflectivity of the reflecting polyester film layer is 94%.

Further, the reflecting film includes the reflecting polyester film layer, the silverplated layer and the protection layer.

The reflecting polyester film layer has a micro-bubble structure, and the micro-bubble has a cell size of 1-10 microns, with a density of 10⁸-10¹⁰/cm³.

Further, the filling particles of the nanometer modified inorganic filler are selected from one of, or a combination of at least two of, titanium dioxide, barium sulfate, calcium carbonate and zinc oxide; and the modification coating material for the inorganic filler is silica and/or alumina. The nanometer modified inorganic filler can be manufactured into masterbatch for use, and the masterbatch is added with a certain amount of additives of the kinds and amounts as commonly used in the field.

Further, the reflecting polyester film layer is manufactured to obtain a micro-bubble structure by physical foaming with supercritical carbon dioxide, and the micro bubbles have a cell size of 1-10 micron and a density of 10⁸-10¹⁰/cm³.

Further, the cell size and density can be adjusted by controlling the proportion of the masterbatch and supercritical carbon dioxide, and 0.02-0.1 cubic meter of liquid carbon dioxide is added to every kilogram of masterbatch. Preferably, 0.05 cubic meters of liquid carbon dioxide is added to every kilogram of masterbatch, or 0.08 cubic meters of liquid carbon dioxide is added to every kilogram of masterbatch.

Further, the thickness of the reflecting polyester film layer is 50-150 μm, the thickness of the silverplated layer is 0.5-1.5 μm, and the thickness of the protection layer is 2-30 μm.

Further, the protection layer is selected from one of a polyester film, a polycarbonate film, a polyethylene film or a polypropylene film. The protection layer may also be called an anti-oxidation film, and has a good antioxygenic property to prevent the silverplated layer from being oxidized.

Further, the silverplated layer is produced by a vacuum sliver plating method, in which silver is coated on one surface of the reflecting polyester film layer, and the vacuum sliver plating comprises vacuum evaporation plating and vacuum sputtering silver plating. The working vacuum degree of the vacuum silver plating is 10-1.0×10⁻¹ Pa, the operating temperature is 850-1000° C., and the film forming speed is 0.01-5 mm/min. After silver-plating, the annealing treatment is performed on the reflecting polyester film layer in the nitrogen or inert gas.

Further, the particle size of the nanometer modified inorganic filler particles is 200-400 nm.

The present invention further provides a method for manufacturing the above-descried silverplated reflecting film, wherein the manufacturing method comprises the following steps:

(1) manufacturing a reflecting polyester film layer;

(2) putting 99.99% silver in a target of a sputtering chamber, with Ar as sputtering gas, a vacuum degree of 10-1.0×10⁻¹ Pa, an operating temperature of 850-1000° C., and a film forming speed of 0.01-5 mm/min; and forming a silverplated layer on the reflecting polyester film layer, and then performing the annealing treatment under a nitrogen atmosphere at a normal temperature to accelerate crystallization of the silverplated layer; and

(3) using a dry-type film covering method, to compound a protection layer film on the silverplated layer obtained by step (2) by a 90° C. heating channel and hot pressurizing, and rolling it up, thus to obtain the silverplated reflecting film.

Further, the protection layer film is manufactured by a tape casting method, in which a polymer is melt-extruded by a single-screw extruder and then is formed into a film on a cold roller, thereby obtaining the protection layer film by drawing and rolling-up.

Further, the physical foaming process for manufacturing the reflecting polyester film layer in step (1) is as follows: melting and plasticating a masterbatch that contains additives and the supercritical carbon dioxide, shearing and mixing the masterbach into a uniform solution in the single-screw extruder, making the solution flow out of a calender through a die head to be cooled and molded, and further bi-directionally stretching the same to obtain the reflecting polyester film layer.

Further, the reflecting polyester film layer is foamed during the stretching process after extrusion. The temperature of processing regions of the single-screw extruder is within the range of 250-300° C.

Compared with the prior art, the silverplated reflecting film provided by the present invention has an excellent reflectivity, and its manufacturing method is simple and easy to operate.

### BRIEF DESCRIPTION OF THE DRAWING

FIG. 1 is a structuralschematic diagram of a silverplated reflecting film provided by the present invention, wherein 1 represents a protection layer, 2 represents a silverplated layer, and 3 represents a reflecting polyester film layer.

### DETAILED DESCRIPTION OF THE INVENTION

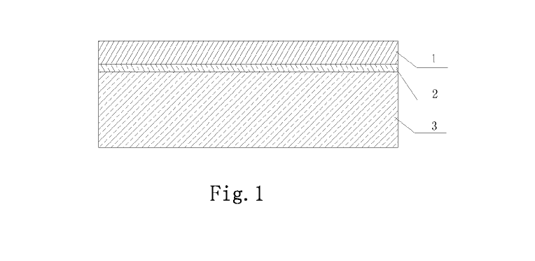

As shown in FIG. 1, a silverplated reflecting film (or called silverplated composite reflecting film, or composite reflecting film) provided by the present invention comprises a reflecting polyester film layer 3, a silverplated layer 2, and a protection layer 1.

The raw materials used in the present invention are common products commercially available in the market, and the nanometer modified inorganic filler that the present invention uses is the material commonly used in the field and has common parameter ranges. They can be manufactured by the users themselves or be bought on the market.

The manufacturing method for the silverplated composite reflecting film provided by the present invention includes the following steps:

(1) manufacturing a reflecting polyester film layer;

(2) putting 99.99% silver in a target of a sputtering chamber, with Ar as sputtering gas, a vacuum degree of 10-1.0×10⁻¹ Pa, an operating temperature of 850-1000° C. and a film forming speed of 0.01-5 mm/min; and forming a silverplated layer on the reflecting polyester film layer and then performing an anneal treatment under nitrogen at the room temperature to accelerate crystallization of the silverplated layer; and

(3) using a dry-type film covering method to compound a previously manufactured protection layer film on the silverplated layer obtained by step (2) by a 90° C. heating channel and hot pressurizing, and rolling it up, thus to obtain the silverplated reflecting film.

Various properties of the silverplated composite reflecting film manufactured according to the abovementioned method were tested using the following method:

Reflectivity: the ColorQuest XE spectrocolorimeter manufactured by Hunterlab Company was used to test the reflectivity of a silverplated composite reflecting film of this invention by an integrating sphere d/8° structure under the D65 light condition in accordance with Standard GB/T3979-2008. The reflectivity data was the weighted average value of the reflectivity of every wavelength with 10 nm interval between 400-700 nm, and the value corresponded to the energy distribution curve of the D65 light source.

### Example 1

A silverplated composite reflecting film of this invention was manufactured according to the above-descried method. The thickness of the reflecting polyester film layer was 50 μm, the thickness of the silverplated layer was 1.5 μm, and the protection layer was polyethylene film with a thickness of 20 μm. The related properties of the obtained composite reflecting film are listed in Table 1.

### Example 2

Another silverplated composite reflecting film of this invention was manufactured according to the above-described method. The thickness of the reflecting polyester film layer was 75 μm, the thickness of the silverplated layer was 1.2 μm, and the protection layer was polypropylene film with a thickness of 15 μm. The related properties of the obtained composite reflecting film are listed in Table 1.

### Example 3

A silverplated composite reflecting film of this invention was manufactured according to the above-described method. The thickness of the reflecting polyester film layer was 100 μm, the thickness of the silverplated layer was 1.0 μm, and the protection layer was polyester film with a thickness of 10 μm. The related properties of the obtained composite reflecting film are listed in Table 1.

### Example 4

A silverplated composite reflecting film of this invention was manufactured according to the above-described method. The thickness of the reflecting polyester film layer was 150 μm, the thickness of the silverplated layer was 0.5 μm, and the protection layer was polycarbonate film with a thickness of 5 μm. The related properties of the obtained composite reflecting film are listed in Table 1.

TABLE 1
Reflectivity of the composite reflecting films of Examples 1-4

| | | Embodiments | | | |
|---|---|---|---|---|---|
| Item | | Example 1 | Example 2 | Example 3 | Example 4 |
| Reflectivity | 550 nm | 99.4 | 99.2 | 99.1 | 99.2 |
| (%) | | | | | |

### Example 5

A silverplated composite reflecting film of this invention was manufactured according to the above-mentioned method. The thickness of the reflecting polyester film layer was 80 μm, the thickness of the silverplated layer was 1.0 μm, and the protection layer was polyethylene film with a thickness of 25 μm.

The reflecting polyester film layer contained 5% nanometer modified inorganic filler, the filling particles were selected from titanium dioxide and barium sulfate (with a weight ratio of 1:1), and the modified coating material thereof was silica. The obtained composite reflecting film had a cell size of 1-10 microns, with the density of 10⁸-10⁹/cm³, and the related properties are listed in Table 2.

### Example 6

A silverplated composite reflecting film of the present invention was manufactured according to the above-mentioned method. The thickness of the reflecting polyester film layer was 120 μm, the thickness of the silverplated layer was 0.8 μm, and the protection layer was polypropylene film with a thickness of 2 μm.

The reflecting polyester film layer contained 25% nanometer modified inorganic filler, the filling particle was selected from titanium dioxide and calcium carbonate (with a weight ratio of 2:1), and the modified coating material thereof was silica and aluminium oxide. The obtained composite reflecting film had a cell size of 1-5 microns, with the density of 10⁸-10⁹/cm³, and the related properties are listed in Table 2.

### Example 7

A silverplated composite reflecting film of the present invention was manufactured according to the above-described method. The thickness of the reflecting polyester film layer was 100 μm, the thickness of the silverplated layer was 1.5 μm, and the protection layer was polyester film with the thickness of 30 μm.

The reflecting polyester film layer contained 10% nanometer modified inorganic filler, the filling particle was calcium carbonate and the modified coating material thereof wa aluminium oxide. The obtained composite reflecting film had a cell size of 3-10 microns, with the density of 10⁹-10¹⁰/cm³, and the related properties are listed in Table 2.

### Example 8

A silverplated composite reflecting film of the present invention was manufactured according to the above-described method. The thickness of the reflecting polyester film layer was 120 μm, the thickness of the silverplated layer was 0.6 μm, and the protection layer was polycarbonate film with the thickness of 15 μm.

The reflecting polyester film layer contained 20% nanometer modified inorganic filler, and the filling particle was zinc oxide, and the modified coating material thereof was silica. The obtained composite reflecting film had a cell size of 1-10 microns, with the density of 10⁸-10¹⁰/cm³, and the related properties are listed in Table 2.

TABLE 2
Reflectivity of the composite reflecting films of Example 5-8

| | | Example | | | |
|---|---|---|---|---|---|
| Item | | Example 5 | Example 6 | Example 7 | Example 8 |
| Reflectivity | 550 nm | 99.3 | 99.5 | 98.9 | 99.4 |
| (%) | | | | | |

### Example 9

A silverplated composite reflecting film of the present invention was manufactured according to the above-described method. The thickness of the reflecting polyester film layer was 100 μm, the thickness of the silverplated layer was 1.0 μm, and the protection layer was polyethylene film with the thickness of 20 μm.

The reflecting polyester film layer containsed 10% nanometer modified inorganic filler, the filling particle was selected from titanium dioxide and barium sulfate (with a weight ratio of 1:1), the modified coating material thereof was silica, and the particle size of the nanometer modified inorganic filler was 200 nm. The temperature of the processing regions of the single-screw extruder was in the range of 250-300° C., the cell size and density were adjusted by controlling the proportion of the masterbatch and supercritical carbon dioxide, 0.02 cubic meters of liquid carbon dioxide was added to every kilogram of masterbatch, and the related properties of the obtained silverplated reflecting film are listed in Table 3.

### Embodiment 10

A silverplated composite reflecting film of the present invention was manufactured according to the above-described method. The thickness of the reflecting polyester film layer was 80 μm, and the thickness of the silverplated layer was 0.8 μm, and the protection layer was polypropylene film with the thickness of 15 μm.

The reflecting polyester film layer contained 20% nanometer modified inorganic filler, the filling particle was titanium dioxide, the modified coating material thereof was silica and aluminium oxide, and the particle size of the nanometer modified inorganic filler was 400 nanometers. The temperature of the processing regions of the single-screw extruder was in the range of 250-300° C., the cell size and density were adjusted by controlling the proportion of the masterbatch and supercritical carbon dioxide, 0.1 cubic meters of liquid carbon dioxide was added to every kilogram of masterbatch, and the related properties of the obtained silverplated reflecting film are listed in Table 3.

### Example 11

A silverplated composite reflecting film of the present invention was manufactured according to the above-described method. The thickness of the reflecting polyester film layer was 60 μm, the thickness of the silverplated layer was 1.0 μm, and the protection layer was polyester film with the thickness of 10 μm.

The reflecting polyester film layer contained 15% nanometer modified inorganic filler, the filling particle was calcium carbonate, the modified coating material was aluminium oxide, and the particle size of the nanometer modified inorganic filler was 300 nanometers. The temperature of the processing regions of the single-screw extruder was in the range of 250-300° C., the cell size and density were adjusted by controlling the proportion of the masterbatch and supercritical carbon dioxide, 0.05 cubic meters of liquid carbon dioxide was added to every kilogram of masterbatch, and the related properties of the obtained silverplated reflecting film are listed in Table 3.

### Example 12

A silverplated composite reflecting film of the present invention was manufactured according to the above-described method. The thickness of the reflecting polyester film layer was 90 μm, the thickness of the silverplated layer was 0.8 μm, and the protection layer was polycarbonate film with the thickness of 5 μm.

The reflecting polyester film layer contained 12% nanometer modified inorganic filler, the filling particle was zinc oxide, the modified coating material thereof was silica, and the particle size of the nanometer modified inorganic filler was 200-400 nanometers. The temperature of the processing regions of the single-screw extruder was 250-300° C., the cell size and density were adjusted by controlling the proportion of the masterbatch and supercritical carbon dioxide, 0.08 cubic meters of liquid carbon dioxide was added to every kilogram of masterbatch, and the related properties of the obtained silverplated reflecting film are listed in Table 3.

TABLE 3
Property test table for the composite reflecting films obtained in
embodiments 9-12

| | | Examples | | | |
|---|---|---|---|---|---|
| | | | Example | Example | |
| Item | | Example 9 | 10 | 11 | Example 12 |
| Reflectivity | 550 nm | 99.5 | 99.4 | 98.5 | 99.6 |
| (%) | | | | | |

### Comparative Example 1

A comparative composite reflecting film was manufactured according to the above-mentioned method, the thickness of the reflecting polyester film layer was 120 μm, and the protection layer was polycarbonate film with the thickness of 15 μm. The difference was the comparative reflecting film did not have a silverplated layer.

The comparative reflecting polyester film layer contained 20% nanometer modified inorganic filler, the filling particle was zinc oxide, and the modified coating material thereof was silica. The obtained composite reflecting film had a cell size of 1-10 microns, with the density of 10⁸-10¹⁰/cm³. The related properties of the comparative reflecting film are listed in Table 4.

### Comparative Example 2

A comparative composite reflecting film was manufactured according to the above-described method. The thickness of the comparative reflecting polyester film layer was 150 μm, the thickness of the silverplated layer was 1.0 μm, and the protection layer was polycarbonate film with the thickness of 20 μm.

The reflecting polyester film layer contained 20% nanometer modified inorganic filler, the filling particle was zinc oxide, and the modified coating material thereof was silica. The difference was the obtained comparative composite reflecting film did not adopt supercritical carbon dioxide for foaming, which did not have the micro-bubble structure of the present invention. The related properties of the obtained comparative reflecting film are listed in Table 4.

### Comparative Example 3

A comparative composite reflecting film was manufactured according to the above-mentioned method, the thickness of the reflecting polyester film layer was 100 μm, the thickness of the silverplated layer was 1.0 μm, and the protection layer was polycarbonate film with the thickness of 10 μm. The difference was the comparative reflecting polyester film layer contained 30% nanometer modified inorganic filler, the filling particle was titanium dioxide, and the modified coating material thereof was silica. In this comparative example, the content of the nanometer modified inorganic filler was too high. The related properties of the obtained reflecting film are listed in Table 4.

TABLE 4
Reflectivity of the comparative composite reflecting films

| | | Examples | | |
|---|---|---|---|---|
| | | Comparative | Comparative | Comparative |
| Item | | example 1 | example 2 | example 3 |
| Reflectivity | 550 nm | 96.3 | 98.2 | 98.9 |
| (%) | | | | |

As shown in the property test data in Table 1 to Table 4, the composite reflecting films provided by the present invention have a higher reflectivity as compared with the reflecting film provided by the comparative examples.

The above described is just the preferable embodiments of the present invention and is not intended to limit the protection scope of the present invention. All equivalent alterations and modifications made according to the present invention will fall within the scope of the claims of the present invention.

1. A silverplated reflecting film, wherein the reflecting film comprises a reflecting polyester film layer, a silverplated layer and a protection layer; the silverplated layer is placed between the reflecting polyester film layer and the protection layer; and the reflecting polyester film layer contains 5-25% nanometer modified inorganic filler comprising filling particles, and the percentage is a percentage by weight.

2. The silverplated reflecting film according to claim 1, wherein the filling particles of the nanometer modified inorganic filler are selected from one of, or a combination of at least two of, titanium dioxide, barium sulfate, calcium carbonate and zinc oxide, and the modified coating material thereof is silica and/or alumina.

3. The silverplated reflecting film according to claim 1, wherein the reflecting polyester film layer has a micro-bubble structure prepared by physical foaming with supercritical carbon dioxide, and the micro-bubbles have a cell size of 1-10 microns and density of 10⁸-10¹⁰/cm³.

4. The silverplated reflecting film according to claim 1, wherein the thickness of the reflecting polyester film layer is 50-150 μm, the thickness of the silverplated layer is 0.5-1.5 μm, and the thickness of the protection layer is 2-30 μm.

5. The silverplated reflecting film according to claim 1, wherein the protection layer is a polyester film, a polycarbonate film, a polyethylene film, or a polypropylene film.

6. The silverplated reflecting film according to claim 1, wherein the silverplated layer is produced by a vacuum sliver plating method, in which silver is coated on one surface of the reflecting polyester film layer, and the vacuum sliver plating includes vacuum evaporation plating and vacuum sputtering silver plating.

7. The silverplated reflecting film according to claim 1, wherein the size of the nanometer modified inorganic filler particles is 200-400 nm.

8. A method for manufacturing a silverplated reflecting film according to claim 1, wherein the manufacturing method comprises the following steps:
(1) manufacturing a reflecting polyester film layer;
(2) putting 99.99% silver in the target of a sputtering chamber, with Ar as a sputtering gas, a vacuum level of 10-1.0×10⁻¹ Pa, a working temperature of 850-1000° C., and a film forming speed of 0.01-5 mm/min; and forming a silverplated layer on the reflecting polyester film layer and then performing annealing treatment under nitrogen at the room temperature; and
(3) using a dry-type film covering method to apply a protection layer film on the silverplated layer obtained by step (2) by passing through and pressing in a heated channel of 90° C., and rolling it up, thus obtaining the silverplated reflecting film.

9. The method for manufacturing the silverplated reflecting film according to claim 8, wherein the protection layer film is manufactured by a tape casting method, in which a polymer is melt-extruded by a single-screw extruder to form a film on a cold roller, thereby obtaining the protection layer film by drawing and rolling up.

10. The method for manufacturing the silverplated reflecting film according to claim 8, wherein the reflecting polyester film layer in step (1) is prepared by a physical foaming process that comprises: melting and plastifying a master batch containing additives and supercritical carbon dioxide, shearing and mixing the same into a uniform solution in the single-screw extruder, extruding the solution out of a calender through a die head to cool, take a shape, and be stretched bi-directionally to obtain the reflecting polyester film layer.
